(19) United States
(12) Patent Application Publication
(10) Pub. No.: US 2026/0223703 A1
(43) Pub. Date: Jul. 30, 2026

(54) CERAMIC SUBSTRATE, METHOD FOR MANUFACTURING SAME, AND POWER MODULE COMPRISING SAME

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 19/146,833

(22) PCT Filed: Jan. 9, 2024
(86) PCT No.: PCT/KR2024/000380

§ 371 Date: Jul. 9, 2025

(30) Foreign Application Priority Data
Jan. 10, 2023 (KR) 10-2023-0003282

(51) Int. Cl. H10W 70/652; H10W 40/20; H10W 70/65; H10W 70/66; H10W 70/692; H10W 90/00

(52) U.S. Cl. CPC H10W 70/6528; H10W 40/235; H10W 70/657; H10W 70/66; H10W 70/692; H10W 90/794

(57) ABSTRACT

The present invention relates to a ceramic substrate, a method for manufacturing same, and a power module comprising same. The ceramic substrate may comprise: a ceramic base material; an upper metal layer and a lower metal layer formed on the upper and lower surfaces of the ceramic base material respectively; and a partial plating layer formed in the upper metal layer, wherein the partial plating layer is formed in a partial area of the upper metal layer where a semiconductor chip is mounted.

### TECHNICAL FIELD

Embodiments of the present disclosure relate to a ceramic substrate, a method of manufacturing the same, and a power module including the same, and more particularly, to a ceramic substrate in which a partial plating layer is formed to improve bonding reliability, a method for manufacturing the same, and a power module including the same.

### BACKGROUND ART

Recently, due to environmental problems and energy-related issues, research has been conducted on electric vehicles. Power modules, which are a component of a power conversion device (inverter or converter) in a drive system of an electric vehicle, include a semiconductor chip for power conversion.

In power modules, a semiconductor chip is bonded to a ceramic substrate. Recently, with increasing demands for high integration, high frequency, and high output of semiconductor chips, high-temperature heat is generated due to high-voltage and high-current operation of the semiconductor chip. For example, when a high-efficiency semiconductor chip such as a SiC chip is employed, a driving temperature of the semiconductor chip may increase to approximately 250° C. or higher. Under such a high driving temperature, it is difficult to achieve a highly reliable bond between the ceramic substrate and the semiconductor chip.

The contents described in the Background Art are to help the understanding of the background of the disclosure, and may include contents that are not related to a disclosed conventional technology.

### SUMMARY OF INVENTION

### Technical Problem

The present disclosure has been devised to solve the above problem, and the present disclosure is directed to a ceramic substrate and a method of manufacturing the same, which enable a highly reliable bond between the ceramic substrate and a semiconductor chip through a partial plating layer formed in an area of the ceramic substrate where the semiconductor chip is mounted.

### Solution to Problem

A ceramic substrate according to an embodiment of the present disclosure for achieving the aforementioned object may include a ceramic base, an upper metal layer and a lower metal layer formed on upper and lower surfaces of the ceramic base, respectively, and a partial plating layer formed on the upper metal layer. The partial plating layer may be formed in a partial area of the upper metal layer where a semiconductor chip is mounted.

The partial plating layer may include, on an upper surface thereof, a first bonding layer disposed to bond the semiconductor chip to the partial plating layer. The first bonding layer may be a silver (Ag) sintered bonding layer. The partial plating layer may be a silver (Ag) plating layer.

A surface roughness of the partial plating layer may range from 0.3 μm to 2.0 μm in terms of Ra. A thickness of the partial plating layer may range from 0.1 μm to 1.0 μm.

The ceramic substrate according to an embodiment of the present disclosure may further include a lower plating layer formed on the lower metal layer. The lower plating layer may be formed in a partial area of the lower metal layer where a heat sink is bonded. The lower plating layer may include at least one of a nickel (Ni) plating layer, a silver (Ag) plating layer, or a gold (Au) plating layer.

A power module according to an embodiment of the present disclosure may include a ceramic substrate including a ceramic base, and an upper metal layer and a lower metal layer formed on upper and lower surfaces of the ceramic base, respectively, a semiconductor chip mounted on the upper metal layer of the ceramic substrate, and a heat sink bonded to the lower metal layer of the ceramic substrate. The ceramic substrate may include a partial plating layer formed in a partial area of the upper metal layer where the semiconductor chip is mounted.

The partial plating layer may include, on an upper surface thereof, a first bonding layer disposed to bond the semiconductor chip to the partial plating layer. The first bonding layer may include a silver (Ag) sintered bonding layer. The partial plating layer may be a silver (Ag) plating layer.

A surface roughness of the partial plating layer may range from 0.3 μm to 2.0 μm in terms of Ra. A thickness of the partial plating layer may range from 0.1 μm to 1.0 μm.

In the power module according to an embodiment of the present disclosure, the ceramic substrate may further include a lower plating layer formed on the lower metal layer. The lower plating may be is formed in a partial area of the lower metal layer where a heat sink is bonded. The lower plating layer may include at least one of a nickel (Ni) plating layer, a silver (Ag) plating layer, or a gold (Au) plating layer.

A method of manufacturing a ceramic substrate according to an embodiment of the present disclosure may include forming an upper metal layer and a lower metal layer on upper and lower surfaces of a ceramic base, respectively, and forming a partial plating layer on the upper metal layer. The forming of the partial plating layer may include forming the partial plating layer in a partial area of the upper metal layer where a semiconductor chip is mounted.

The forming of the partial plating layer may include forming, on the upper metal layer, a cover layer having a pattern hole formed in a shape corresponding to the partial area, performing plating so that the partial plating layer is formed in the pattern hole, and removing the cover layer.

The forming of the cover layer may include forming a photoresist layer on the upper metal layer, disposing a mask that covers a remaining area other than the partial area on the photoresist layer, and exposing the photoresist layer, and forming the pattern hole in the photoresist layer by developing an exposed portion.

The performing of the plating may include forming a partial plating layer by electroplating or electroless plating a silver (Ag) plating layer.

The method according to an embodiment of the present disclosure may further include forming a lower plating layer on the lower metal layer. The forming of the lower plating layer may include forming the lower plating layer in a partial area of the lower metal layer where a heat sink is mounted.

The forming of the lower plating layer may include forming the lower plating layer by electroplating or electroless plating a plating layer including at least one of a nickel (Ni) plating layer, a silver (Ag) plating layer, or a gold (Au) plating layer.

### Advantageous Effects of Invention

According to the present disclosure, a partial plating layer may be formed in a partial area of a ceramic substrate where a semiconductor chip is mounted, thereby preventing electrical short circuits from occurring due to a silver migration phenomenon, and a highly reliable bond between a ceramic substrate and a semiconductor chip can be achieved.

Furthermore, according to the present disclosure, the adhesion of the partial plating layer to an Ag sintered bonding layer disposed on an upper surface of the partial plating layer may be enhanced by imparting surface roughness to the upper surface of the partial plating layer.

In addition, according to the present disclosure, because the partial plating layer is formed in a partial area of an upper metal layer where the semiconductor chip is mounted, the amount of silver to be plated is reduced compared to the case where silver is formed over the entire surface of the upper metal layer, thereby reducing product costs and preventing peeling of the plating layer.

Furthermore, according to the present disclosure, a lower plating layer is formed in a partial area of the ceramic substrate where a heat sink is bonded, thereby enabling a highly reliable bond between the ceramic substrate and the heat sink, and being effective in preventing silver diffusion and in dissipating heat.

### BRIEF DESCRIPTION OF DRAWINGS

FIG. 1 is a plan view illustrating a ceramic substrate according to an embodiment of the present disclosure.

FIG. 2 is a sectional view taken along line A-A′ of FIG. 1.

FIG. 3 is a sectional view taken along line B-B′ of FIG. 1.

FIG. 4 is a sectional view illustrating a power module in which a semiconductor chip and a heat sink are bonded to the ceramic substrate shown in FIG. 2.

FIG. 5 is a photograph showing another example of a ceramic substrate according to an embodiment of the present disclosure.

FIG. 6 is a photograph showing a silver migration phenomenon.

FIG. 7 is a flowchart illustrating a method of manufacturing a ceramic substrate according to an embodiment of the present disclosure.

### DESCRIPTION OF EMBODIMENTS

Hereinafter, embodiments of the present disclosure will be described in detail with reference to the accompanying drawings.

Embodiments are provided to more fully explain the present disclosure to a person having ordinary knowledge in the art to which the present disclosure pertains. The following embodiments may be modified in various other forms, and the scope of the present disclosure is not limited to the following embodiments. Rather, these embodiments are provided to make the present disclosure more thorough and complete and to fully convey the spirit of the present disclosure.

Terms used in this specification are used to describe a specific embodiment, and are not intended to limit the present disclosure. Furthermore, in this specification, an expression of the singular number may include an expression of the plural number unless clearly defined otherwise in the context.

In the description of the embodiments, when it is described that each layer (film), area, pattern, or structure is formed “on” or “under” each substrate, layer (film), area, pad, or pattern, this includes both expressions, including that a layer is formed on another layer “directly” or “with a third layer interposed between the two layers (indirectly)”. Furthermore, a criterion for the term “on or under of each layer” is described based on the drawings.

The drawings are merely for enabling the spirit of the present disclosure to be understood, and it should not be interpreted that the scope of the present disclosure is limited by the drawings. Furthermore, in the drawings, a relative thickness or length or a relative size may be enlarged for convenience and the clarity of description.

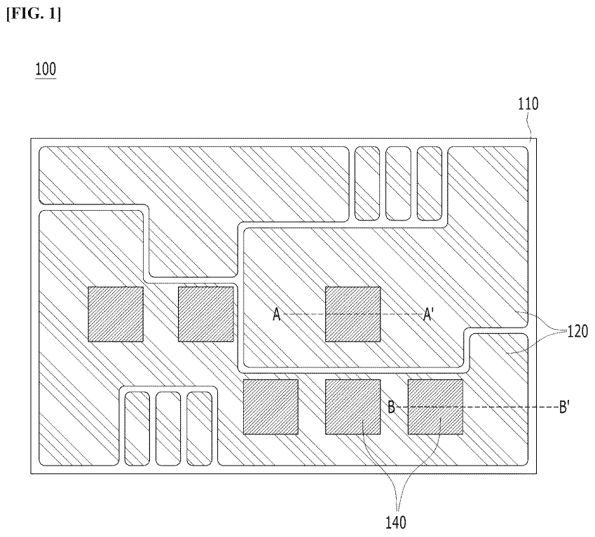

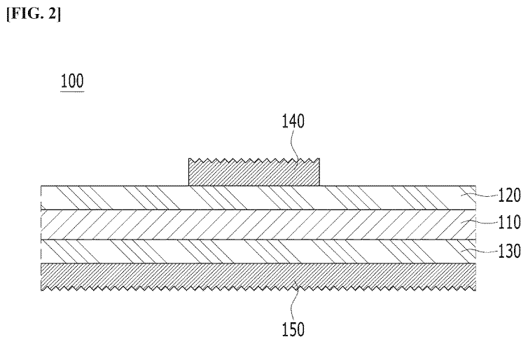

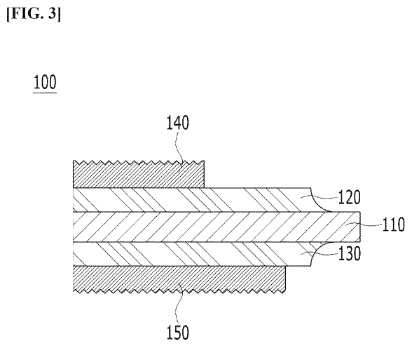

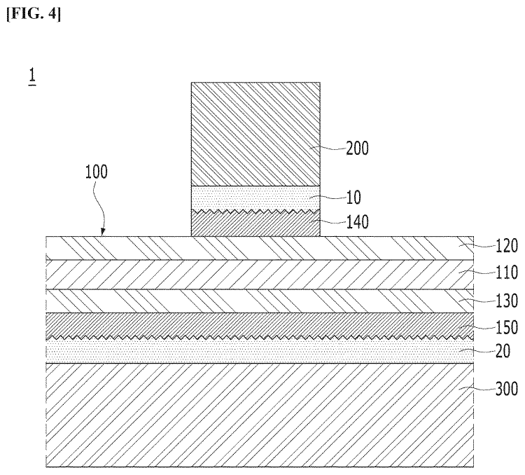

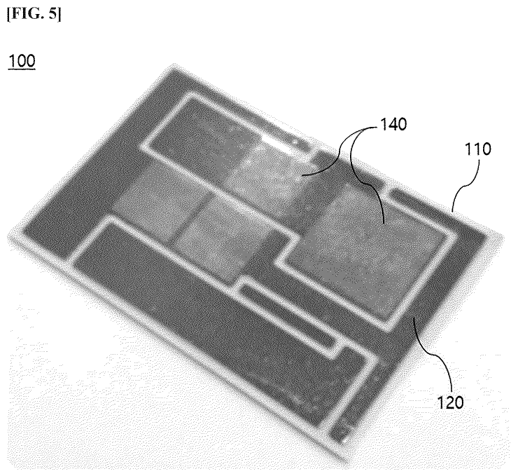

FIG. 1 is a plan view illustrating a ceramic substrate according to an embodiment of the present disclosure. FIG. 2 is a sectional view taken along line A-A′ of FIG. 1. FIG. 3 is a sectional view taken along line B-B′ of FIG. 1. FIG. 4 is a sectional view illustrating a power module in which a semiconductor chip and a heat sink are bonded to the ceramic substrate shown in FIG. 2. FIG. 5 is a photograph showing another example of a ceramic substrate according to an embodiment of the present disclosure. For reference, in the sectional views of FIGS. 2 to 4, a relative thickness or length or a relative size has been exaggerated and shown, for convenience and clarity of a description.

As illustrated in FIGS. 1 to 3, a ceramic substrate 100 according to an embodiment of the present disclosure may include a ceramic base 110, an upper metal layer 120, a lower metal layer 130, and a partial plating layer 140.

The ceramic base 110 may be formed of an insulating ceramic material having high thermal conductivity and excellent flexural strength. For example, the ceramic base 110 may be formed of any one of Al₂O₃, AlN, Si₃N₄, or zirconia toughened alumina (ZTA).

The upper metal layer 120 and the lower metal layer 130 may be formed by brazing a metal foil to each of opposite surfaces of the ceramic base 110. The upper metal layer 120 may be formed as a circuit pattern capable of electrical circuit connection to a semiconductor chip 200 by etching or machining. The upper metal layer 120 and the lower metal layer 130 may be formed of any one of Cu, a Cu alloy (such as CuMo), or Al. The brazing may employ a brazing layer formed of an alloy material including at least one of Ag, AgCu, or AgCuTi. Heat treatment for brazing may be performed at a temperature ranging from 780° C. to 900° C. As such, the ceramic substrate 100 may be an active metal brazing (AMB) substrate. The AMB substrate exhibits excellent durability and heat dissipation performance. Although embodiments are described using the AMB substrate as an example, the ceramic substrate 100 may also be a direct bonding copper (DBC) substrate. It is desirable that, in the ceramic substrate 100, the ceramic base 110 be formed to have a thickness of 0.25 mm or more, and each of the upper metal layer 120 and the lower metal layer 130 be formed to have a thickness of 0.127 mm or more.

The ceramic substrate 100 according to an embodiment of the present disclosure is characterized in that the partial plating layer 140 is formed in a partial area of the upper metal layer 120 where the semiconductor chip 200 is mounted. The partial plating layer 140 may be formed by electroplating or electroless plating using an Ag-containing plating solution.

FIG. 4 is a sectional view illustrating a power module in which the semiconductor chip 200 and a heat sink 300 are bonded to the ceramic substrate 100 shown in FIG. 2.

Referring to FIG. 4, the power module 1 according to an embodiment of the present disclosure may include the semiconductor chip 200 mounted on the upper metal layer 120 of the ceramic substrate 100, and the heat sink 300 bonded to the lower metal layer 130 of the ceramic substrate 100. Here, the partial plating layer 140 may include, on an upper surface thereof, a first bonding layer 10 disposed to bond the semiconductor chip 200 to the partial plating layer 140. The semiconductor chip 200 may be a semiconductor chip 200 using SiC, GaN, an insulated gate bipolar transistor (IGBT), or the like. The first bonding layer 10 may be an Ag sintered bonding layer. In the case of SiC or GaN elements that operate at high temperatures, because the operation is performed at temperatures of 200° C. or more, existing low-melting-point solder bonding is disadvantageous in maintaining bonding characteristics and securing bonding strength. The Ag sintered bonding layer has high thermal stability and excellent bonding strength, as the melting point of a sintered body increases to 700° C. or more after bonding. Therefore, it is desirable that the semiconductor chip 200 be bonded by an Ag sintered bonding layer using an Ag particle-containing paste or an Ag particle-based film.

To improve bonding strength with the first bonding layer 10, which is an Ag sintered bonding layer, the partial plating layer 140 may be formed as an Ag plating layer, which is formed of the same metal as the Ag sintered bonding layer. Referring to FIGS. 1 to 5, the partial plating layer 140 may provide surface roughness to a bonding surface with the first bonding layer 10. The surface roughness refers to the degree of irregularities formed on a surface of the partial plating layer 140, and may be expressed in units such as center-line surface roughness (Ra), maximum height (Rmax), and ten-point average roughness (Rz). A desirable example of the surface roughness of the partial plating layer 140 may be represented by an Ra value ranging from 0.3 μm to 2.0 μm. The partial plating layer 140 may have irregularities formed on a surface thereof, thereby increasing the specific surface area and enhancing bonding strength with the Ag sintered bonding layer disposed on an upper surface of the partial plating layer 140. If the surface roughness (Ra) of the partial plating layer 140 is less than 0.3 μm, there is a problem in that the surface of the partial plating layer 140 becomes excessively smooth, which degrades adhesion to the Ag sintered bonding layer. Furthermore, if the surface roughness (Ra) of the partial plating layer 140 exceeds 2.0 μm, the surface of the partial plating layer 140 may become excessively rough, and the attachment of the Ag sintered bonding layer may fail locally. Therefore, in the present disclosure, to improve the bonding strength with the Ag sintered bonding layer, it is desirable that the surface roughness (Ra) of the partial plating layer 140 range from 0.3 μm to 2.0 μm. When the surface roughness of the partial plating layer 140 ranges from 0.3 μm to 2.0 μm in terms of Ra, the Rz value may be in the range from 3 μm to 8 μm, and the Rmax value may be in the range from 5 μm to 15 μm.

In addition, it is desirable that the partial plating layer 140 be formed to have a thickness ranging from 0.1 μm to 1.0 μm. When the thickness of the partial plating layer 140 is less than 0.1 μm, it is difficult to provide surface roughness. When the thickness of the partial plating layer 140 exceeds 1.0 μm, the processing time required to form the partial plating layer 140 becomes longer, which may reduce mass productivity.

It is desirable that the partial plating layer 140 be formed in the partial area of the upper metal layer 120 where the semiconductor chip 200 is mounted. If the partial plating layer 140 including Ag is formed to cover the entire surface of the upper metal layer 120, an electrical short circuit may occur due to a silver migration phenomenon.

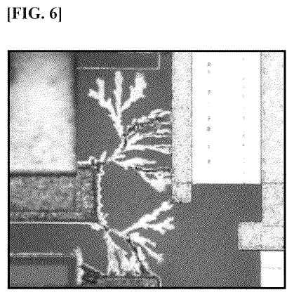

FIG. 6 is a photograph showing a silver migration phenomenon. In the case where the ceramic substrate 100 having silver plated over the entire surface is exposed to an external environment, particularly a high-temperature and high-humidity environment, a migration phenomenon in which silver ions diffuse in the form of dendrites, as shown in FIG. 6, occurs. The migration phenomenon causes short circuits between circuits and degrades the reliability of the ceramic substrate 100. In contrast, in the ceramic substrate 100 according to an embodiment of the present disclosure, because the partial plating layer 140 is formed in the partial area of the upper metal layer 120 where the semiconductor chip 200 is mounted, a sufficient distance is ensured between the partial plating layers 140, and therefore, there is no risk of migration.

In the case where the partial plating layer 140 is formed over the entire surface of the upper metal layer 120 rather than in a limited area, a surface of the plating layer other than the partial area where the semiconductor chip 200 is mounted may be exposed to the air, thus resulting in oxidation and degradation. Furthermore, because silver is expensive, an increase in the surface area of the plating layer increases the amount of silver used, thereby raising production costs and reducing economic efficiency. In addition, as illustrated in FIG. 3, the upper metal layer 120 has an outer peripheral portion formed with a curved inclined surface by etching using an etching solution. Accordingly, when the partial plating layer 140 is plated over the entire surface of the upper metal layer 120, the plating layer may not properly adhere to the curved inclined surface and may be peeled off, and a short circuit may occur between the peeled plating layer and the semiconductor chip 200.

On the other hand, in the case where the partial plating layer 140 is formed in the partial area of the upper metal layer 120 where the semiconductor chip 200 is mounted, the surface of the partial plating layer 140 is bonded to the first bonding layer 10 and is not exposed to the air, thereby preventing oxidation. In addition, because the amount of silver to be plated is reduced, production costs can be reduced. Furthermore, since it is not necessary to form a plating layer on the outer peripheral portion of the upper metal layer 120, which is formed as a curved inclined surface, problems such as peeling of the plating layer do not occur, and short circuits can be prevented. Furthermore, the partial plating layer 140 enables a highly reliable bond between the ceramic substrate 100 and the semiconductor chip 200, and is also effective in preventing the diffusion of silver and in dissipating heat.

The ceramic substrate 100 according to an embodiment of the present disclosure may further include a lower plating layer 150 formed on the lower metal layer 130. The lower plating layer 150 may be formed in a partial area of the lower metal layer 130 where the heat sink 300 is bonded. The lower plating layer 150 may be formed by electroplating or electroless plating. As illustrated in FIG. 4, a second bonding layer 20 for bonding the heat sink 300 may be disposed on a lower surface of the lower plating layer 150. The heat sink 300 may be formed of any one of Cu, Al, or a Cu alloy having high thermal conductivity for heat dissipation. The second bonding layer 20 may be an Ag sintered bonding layer having high thermal stability and excellent bonding strength. Here, the lower plating layer 150 may be an Ag plating layer formed using an Ag-containing plating solution to improve bonding strength with the second bonding layer 20, which is an Ag sintered bonding layer. The lower plating layer 150 may provide surface roughness to a bonding surface with the second bonding layer 20. In addition, the lower plating layer 150 may be formed to include a nickel (Ni) plating layer and a gold (Au) plating layer. For example, the lower plating layer 150 may be formed by stacking an Au plating layer or an Ag plating layer on the Ni plating layer in order to prevent oxidation of the Ni plating layer and to improve bonding strength, and may be formed by electroplating. The lower plating layer 150 enables a highly reliable bond between the ceramic substrate 100 and the heat sink 300, and is also effective in preventing the diffusion of silver and in dissipating heat.

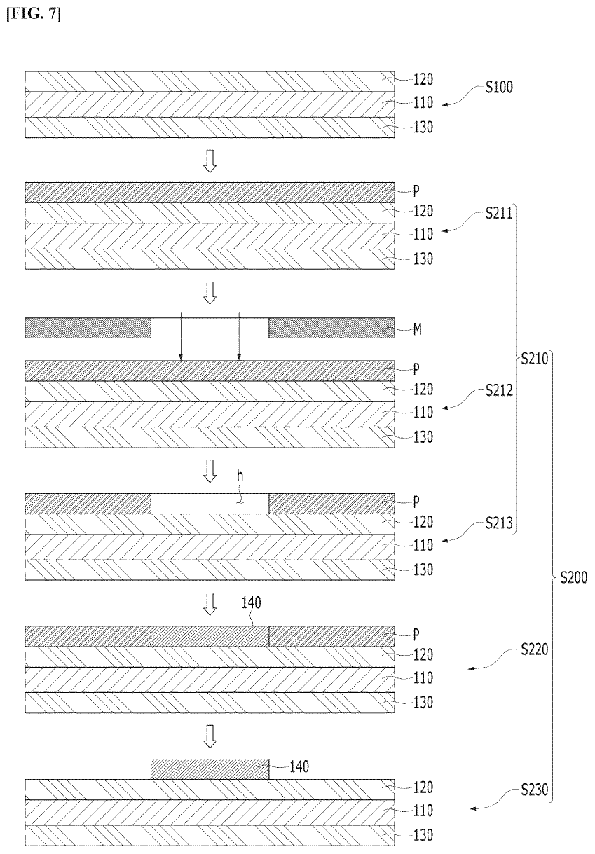

FIG. 7 is a flowchart illustrating a method of manufacturing the ceramic substrate 100 according to an embodiment of the present disclosure.

As illustrated in FIG. 7, the method for manufacturing the ceramic substrate 100 according to an embodiment of the present disclosure may include step S100 of forming the upper metal layer 120 and the lower metal layer 130 on the upper and lower surfaces of the ceramic base 110, and step S200 of forming the partial plating layer 140 on the upper metal layer 120.

In step S200 of forming the partial plating layer 140, the partial plating layer 140 may be formed in the partial area of the upper metal layer 120 where the semiconductor chip 200 is mounted. The partial plating layer 140 may be formed through various processes such as electroplating, electroless plating, or physical vapor deposition. In the present embodiment, the partial plating layer 140 will be described as being formed by electroplating or electroless plating in order to achieve a uniform thickness along the surface thereof.

Referring to FIG. 7, step S200 of forming the partial plating layer 140 may include: step S210 of forming a cover layer having a pattern hole h corresponding to the partial area of the upper metal layer 120 where the semiconductor chip 200 is mounted, step S220 of performing plating so that the partial plating layer 140 is formed within the pattern hole h, and step S230 of removing the cover layer.

Step S210 of forming the cover layer may include step S211 of forming a photoresist layer P on the upper metal layer 120, step S212 of exposing the photoresist layer P while masking, using a mask M, a remaining area other than the partial area where the semiconductor chip 200 is mounted, and step S213 of forming a pattern hole h in the photoresist layer P by developing the exposed portion. In the present embodiment, the cover layer may be a photoresist layer P patterned through a photolithography process.

In step S211 of forming the photoresist layer P, the photoresist layer P may be formed by applying a dry film or a liquid photoresist onto the upper metal layer 120. Here, the dry film has the advantage of simplifying the manufacturing process because the dry film has a uniform thickness and does not require a separate drying process.

In step S212 of exposing the photoresist layer, the mask M that covers the remaining area other than the partial area where the semiconductor chip 200 is mounted may be placed on the photoresist layer P, and a light source configured to emit ultraviolet (UV) light or the like may be used to irradiate the photoresist layer P. In this way, as light from the light source is irradiated onto the photoresist layer P through the mask M, a pattern of the mask M may be transferred onto the photoresist layer P. Here, a positive-type photoresist is a type in which only the portions exposed to the light source are developed, whereas a negative-type photoresist is a type in which only the unexposed portions are developed. Although an example in which a positive-type photoresist layer P is used is described in the present embodiment, a negative-type photoresist may also be used.

In step S213 of forming the pattern hole h, when the photoresist layer P is developed after exposure, the partial area where the semiconductor chip 200 is mounted is removed, thereby forming the pattern hole h.

Subsequently, in the plating step S220, electroplating or electroless plating may be performed using an Ag-containing plating solution so that the partial plating layer 140 is formed in the pattern hole h. That is, in the plating step S220, the partial plating layer 140 may be formed, with the photoresist layer P as a barrier, in the pattern hole h corresponding to the partial area where the semiconductor chip 200 is mounted.

Subsequently, in step S230 of removing the cover layer, the photoresist layer P may be removed, so that the remaining area of the upper metal layer 120 except for the partial area where the partial plating layer 140 is formed may be exposed.

Step S200 of forming the partial plating layer 140 may further include the step of imparting surface roughness to the partial plating layer 140. In the step of imparting the surface roughness, the surface roughness of the partial plating layer 140 may be formed in a range from 0.3 μm to 2.0 μm in terms of Ra. The surface roughness of the partial plating layer 140 may be formed by etching, machining, or the like.

Furthermore, the method of manufacturing the ceramic substrate 100 according to an embodiment of the present disclosure may further include the step of forming the lower plating layer 150 on the lower metal layer 130. Although not shown, the step of forming the lower plating layer 150 may be performed by a photolithography process in the same manner as step S200 of forming the partial plating layer 140. In addition, the step of forming the lower plating layer 150 may include forming the lower plating layer 150 by electroplating or electroless plating a plating layer including at least one of a Ni plating layer, an Ag plating layer, or an Au plating layer.

As described above, in the present disclosure, a partial plating layer may be formed in a partial area of a ceramic substrate where a semiconductor chip is mounted, thereby preventing electrical short circuits from occurring due to a silver migration phenomenon, and a highly reliable bond between a ceramic substrate and a semiconductor chip can be achieved.

The above description is merely a description of the technical spirit of the present disclosure, and those skilled in the art may change and modify the present disclosure in various ways without departing from the essential characteristic of the present disclosure. Accordingly, the embodiments described in the present disclosure should not be construed as limiting the technical spirit of the present disclosure, but should be construed as describing the technical spirit of the present disclosure. The technical spirit of the present disclosure is not restricted by the embodiments. The range of protection of the present disclosure should be construed based on the following claims, and all of technical spirits within an equivalent range of the present disclosure should be construed as being included in the scope of rights of the present disclosure.

1. A ceramic substrate comprising:
a ceramic base;
an upper metal layer and a lower metal layer formed on upper and lower surfaces of the ceramic base, respectively; and
a partial plating layer formed on the upper metal layer,
wherein the partial plating layer is formed in a partial area of the upper metal layer where a semiconductor chip is mounted.

2. The ceramic substrate of claim 1,
wherein the partial plating layer includes, on an upper surface thereof, a first bonding layer disposed to bond the semiconductor chip to the partial plating layer, and
wherein the first bonding layer comprises a silver (Ag) sintered bonding layer.

3. The ceramic substrate of claim 1, wherein a surface roughness of the partial plating layer ranges from 0.3 μm to 2.0 μm in terms of Ra.

4. The ceramic substrate of claim 1, wherein a thickness of the partial plating layer ranges from 0.1 μm to 1.0 μm.

5. The ceramic substrate of claim 1, wherein the partial plating layer comprises a silver (Ag) plating layer.

6. The ceramic substrate of claim 1, further comprising a lower plating layer formed on the lower metal layer,
wherein the lower plating layer is formed in a partial area of the lower metal layer where a heat sink is bonded.

7. The ceramic substrate of claim 6, wherein the lower plating layer includes at least one of a nickel (Ni) plating layer, a silver (Ag) plating layer, or a gold (Au) plating layer.

8. A power module comprising:
a ceramic substrate including a ceramic base, and an upper metal layer and a lower metal layer formed on upper and lower surfaces of the ceramic base, respectively;
a semiconductor chip mounted on the upper metal layer of the ceramic substrate; and
a heat sink bonded to the lower metal layer of the ceramic substrate,
wherein the ceramic substrate includes a partial plating layer formed in a partial area of the upper metal layer where the semiconductor chip is mounted.

9. The power module of claim 8,
wherein the partial plating layer includes, on an upper surface thereof, a first bonding layer disposed to bond the semiconductor chip to the partial plating layer, and
wherein the first bonding layer comprises a silver (Ag) sintered bonding layer.

10. The power module of claim 8, wherein a surface roughness of the partial plating layer ranges from 0.3 μm to 2.0 μm in terms of Ra.

11. The power module of claim 8, wherein a thickness of the partial plating layer ranges from 0.1 μm to 1.0 μm.

12. The power module of claim 8, wherein the partial plating layer comprises a silver (Ag) plating layer.

13. The power module of claim 8,
wherein the ceramic substrate further comprises a lower plating layer formed on the lower metal layer, and
wherein the lower plating layer is formed in a partial area of the lower metal layer where a heat sink is bonded.

14. The power module of claim 13, wherein the lower plating layer includes at least one of a nickel (Ni) plating layer, a silver (Ag) plating layer, or a gold (Au) plating layer.

15. A method of manufacturing a ceramic substrate, the method comprising:
forming an upper metal layer and a lower metal layer on upper and lower surfaces of a ceramic base, respectively; and
forming a partial plating layer on the upper metal layer,
wherein the forming of the partial plating layer comprises forming the partial plating layer in a partial area of the upper metal layer where a semiconductor chip is mounted.

16. The method of claim 15, wherein the forming of the partial plating layer comprises:
forming, on the upper metal layer, a cover layer having a pattern hole formed in a shape corresponding to the partial area;
performing plating so that the partial plating layer is formed in the pattern hole; and
removing the cover layer.

17. The method of claim 16, wherein the forming of the cover layer comprises:
forming a photoresist layer on the upper metal layer;
disposing a mask that covers a remaining area other than the partial area on the photoresist layer, and exposing the photoresist layer; and
forming the pattern hole in the photoresist layer by developing an exposed portion.

18. The method of claim 16, wherein the performing of the plating comprises forming a partial plating layer by electroplating or electroless plating a silver (Ag) plating layer.

19. The method of claim 15, further comprising forming a lower plating layer on the lower metal layer,
wherein the forming of the lower plating layer comprises forming the lower plating layer in a partial area of the lower metal layer where a heat sink is mounted.

20. The method of claim 19, wherein the forming of the lower plating layer comprises forming the lower plating layer by electroplating or electroless plating a plating layer including at least one of a nickel (Ni) plating layer, a silver (Ag) plating layer, or a gold (Au) plating layer.
